(19) United States
(12) Patent Application Publication
(10) Pub. No.: US 2025/0282021 A1
(43) Pub. Date: Sep. 11, 2025

(54) Disc Grinding for Semiconductor Wafers on Polishing System

(71) Applicant: Wolfspeed, Inc., Durham, NC (US)

(72) Inventors: Simon Bubel, Carrboro, NC (US); Dinusha Priyadarshani Karunaratne, Cary, NC (US)

(21) Appl. No.: 18/598,871

(22) Filed: Mar. 7, 2024

(51) Int. Cl. B24B 37/24; B24B 55/02; B24B 57/02; H01L 21/04; H01L 21/463

(52) U.S. Cl. CPC B24B 37/245; B24B 55/02; B24B 57/02; H01L 21/0475; H01L 21/463

(57) ABSTRACT

Grind discs for semiconductor polishing systems are provided. In one example, a semiconductor workpiece polishing system includes a platen configured to rotate about an axis. The semiconductor workpiece polishing system further includes a grind disc on the platen, the grind disc has an abrasive surface configured to grind silicon carbide. The semiconductor workpiece polishing system includes a workpiece carrier operable to bring a silicon carbide semiconductor workpiece into contact with the grind disc to implement a grinding operation on the silicon carbide semiconductor workpiece. The grinding operation reduces a thickness of the silicon carbide semiconductor workpiece by at least about 0.5 microns.

### FIELD

The present disclosure relates generally to semiconductor workpieces and fabrication processes for semiconductor workpieces, such as semiconductor wafers used in semiconductor device fabrication.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), Schottky diodes, bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials. The fabrication process may require processing of wide bandgap semiconductor wafers, such as silicon carbide semiconductor wafers.

### SUMMARY

Aspects and advantages of embodiments of the present disclosure will be set forth in part in the following description, or may be learned from the description, or may be learned through practice of the embodiments.

One example aspect of the present disclosure is directed to a semiconductor workpiece polishing system. The semiconductor workpiece polishing system includes a platen configured to rotate about an axis. The semiconductor workpiece polishing system further includes a grind disc on the platen, the grind disc having an abrasive surface configured to grind silicon carbide. The semiconductor workpiece polishing system further includes a workpiece carrier operable to bring a silicon carbide semiconductor workpiece into contact with the grind disc to implement a grinding operation on the silicon carbide semiconductor workpiece. The grinding operation reduces a thickness of the silicon carbide semiconductor workpiece by at least about 0.5 microns.

Another example aspect of the present disclosure is directed to a method for grinding a silicon carbide semiconductor workpiece using a semiconductor workpiece polishing system. The method includes providing an entire surface of the silicon carbide semiconductor workpiece against a grind disc. The grind disc includes an abrasive containing material configured to grind silicon carbide. The grind disc is on a platen of the semiconductor workpiece polishing tool. The abrasive containing material is on at least about 75% of a surface area of a surface of the grind disc. The method further includes imparting relative motion between the grind disc and the silicon carbide semiconductor workpiece. The method further includes performing a grinding operation on the entire surface of the silicon carbide semiconductor workpiece. The grinding operation reduces a thickness of the silicon carbide semiconductor workpiece by at least about 0.5 microns.

Another example aspect of the present disclosure is directed to a semiconductor wafer comprising silicon carbide, the semiconductor wafer having an irregular grind pattern. The semiconductor wafer has an edge roll over 10 millimeters from a peripheral edge of the semiconductor wafer of less than about 0.7 microns.

Another example aspect of the present disclosure is directed to a semiconductor wafer, comprising a silicon carbide surface. The semiconductor wafer has an irregular grind pattern on the silicon carbide surface, wherein the semiconductor wafer has a center dimple within a center dimple diameter of 10 millimeters from a center of the semiconductor wafer that is less than 1 micron.

Another example aspect of the present disclosure is directed to a semiconductor wafer comprising silicon carbide. The semiconductor wafer has a non-Blanchard grind pattern, wherein the semiconductor wafer has an edge roll over 10 mm from a peripheral edge of the semiconductor wafer of less than about 0.7 microns.

Another example aspect of the present disclosure is directed to a grind disc for grinding silicon carbide semiconductor wafers. The grind disc has a diameter of about 150 millimeters or greater. The grind disc has an abrasive surface with an abrasive containing material configured to grind silicon carbide. The abrasive surface is at least about 75% of a surface area of a surface of the grind disc.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example semiconductor wafer polishing system according to example embodiments of the present disclosure;

FIGS. 2-10 depict example grind discs according to example embodiments of the present disclosure;

FIG. 11 depicts a cross-sectional view of an example workpiece carrier according to example embodiments of the present disclosure;

FIG. 12 depicts a cross-sectional view of an example workpiece carrier according to example embodiments of the present disclosure;

FIG. 13 depicts a plan view of an example workpiece carrier according to example embodiments of the present disclosure;

FIG. 14 depicts an example grind disc according to example embodiments of the present disclosure;

FIG. 15 depicts an example semiconductor wafer according to example embodiments of the present disclosure;

FIG. 16 depicts an example semiconductor wafer with a Blanchard grind pattern;

FIG. 17 depicts example determination of center dimple according to example embodiments of the present disclosure;

FIG. 18 depicts example determination of edge roll according to example embodiments of the present disclosure;

FIG. 19 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc.). Example surface processing operations may include grinding operations, lapping operations, and polishing operations.

Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces, such as other wide bandgap semiconductor workpieces. Other semiconductor workpieces may include carrier substrates, ingots, boules, polycrystalline substrates, monocrystalline substrates, bulk materials having a thickness of greater than 1 mm, such as greater than about 5 mm, such as greater than about 10 mm, such as greater than about 20 mm, such as greater than about 50 mm, such as greater than about 100 mm, to 200 mm, etc.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grind teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Grinding may include coarse grinding operations and fine grinding operations. Coarse grinding operations may be used to reduce a thickness of a silicon carbide semiconductor wafer by about 20 microns to about 200 microns, such by about 25 microns to about 100 microns, such as by about 25 microns to about 80 microns, such as by about 40 microns to about 60 microns, or the like. Fine grinding operations may be used to reduce a thickness of a silicon carbide semiconductor wafer by about 1 micron to about 20 microns, such as by about 3 microns to about 15 microns, such as by about 5 microns to about 10 microns, or the like. After grinding, the silicon carbide semiconductor wafer may be subject to other surface processing operations, such as lapping operations and/or polishing operations, such as chemical mechanical polishing (CMP) operations).

Grinding silicon carbide semiconductor wafers may pose several challenges due to the inherent properties of the material. Silicon carbide is an extremely hard and brittle compound with a high level of abrasiveness, making the grinding process more demanding. One challenge is the potential for excessive tool wear and heat generation during grinding, which can affect the quality of the finished product. The hardness of silicon carbide may also lead to the formation of cracks or fractures if not properly managed, impacting the structural integrity of the material. Additionally, achieving precise dimensions and surface finishes can be challenging due to the resistance of silicon carbide to abrasion. Controlling parameters such as grinding wheel selection, speed, feed rates, and cooling mechanisms may be important to overcoming these challenges and to providing for the successful fabrication of silicon carbide components with the desired properties and performance.

Some grinding systems (e.g., Blanchard grinders) may include a rotary table and a vertical spindle that holds a grinding wheel with a plurality of abrasive grind teeth. The semiconductor wafer may be mounted on the rotary table, for instance, using a chuck. In some examples, the axis of rotation of the semiconductor wafer is not aligned with the axis of rotation of the grind wheel. During the grinding process, the grind teeth on the grinding wheel traverse across a portion of the surface of the workpiece, removing material from the semiconductor wafer.

Blanchard grinders may only work on a small area of a semiconductor wafer surface at a time. As a result, Blanchard grinding often presents challenges with uniform material removal from a semiconductor wafer surface. Semiconductor wafers that have been subjected to Blanchard grinding may include a high center dimple, high edge roll, or other non-uniformities in wafer shape.

As used herein, center dimple refers to flatness non-uniformity in a center portion of a semiconductor wafer that has a lower thickness relative to the remainder of the semiconductor wafer. A center dimple may result from the configuration of a Blanchard grinder, where the grind teeth typically always pass through the center portion of the semiconductor wafer during a grinding operation.

Edge roll refers to a reduced thickness at the periphery of a semiconductor wafer. Edge roll may result from a Blanchard grinder by the repetition of grind teeth contacting the peripheral edge of the semiconductor wafer during a grinding operation, resulting of the removal of more materials at the semiconductor wafer edge relative to the remainder of the semiconductor wafer.

Polishing tools (e.g., CMP tools) may be used after grinding operations to polish and/or smooth a semiconductor wafer surface. Polishing tools, such as CMP tools, may use a combination of chemical and mechanical forces to remove excess materials from a wafer surface, ensuring optimal flatness and smoothness. Polishing tools, such as CMP tools, may include a rotating platen, polishing pad, and a slurry containing abrasive particles and chemical agents. As the wafer is pressed against the polishing pad and rotated, the abrasive slurry chemically reacts with and/or mechanically removes material, resulting in a highly planar and smooth surface.

Aspects of the present disclosure are directed to polishing tools (e.g., CMP tools) that are adapted to implement a grinding operation on a silicon carbide wafer. In some examples, the grinding operation may be a coarse grinding operation. More specifically, the coarse grinding operation may reduce a thickness of the semiconductor wafer by about 20 microns to about 100 microns, such as by about 20 microns to about 80 microns, such as by about 40 microns to about 60 microns, or the like. The grinding operation may be a fine grinding operation. More specifically, the fine grinding operation may reduce a thickness of a silicon carbide semiconductor wafer by about 0.5 microns to about 20 microns, such as by about 3 microns to about 15 microns, such as by about 5 microns to about 10 microns, or the like.

More specifically, according to example embodiments of the present disclosure, a polishing system (e.g., a CMP system) includes a platen (e.g., a table) configured to rotate about an axis. The polishing system can include a grind disc on the platen. The grind disc can have an abrasive surface that is configured to grind silicon carbide. The polishing system can include a workpiece carrier operable to bring a silicon carbide semiconductor wafer into contact with the grind disc to implement a grinding operation.

More specifically, the platen may include a receptacle. The receptacle may typically hold a polishing pad for implementation of a CMP process. However, instead of holding a polishing pad, the receptacle holds a grind disc (e.g., an abrasive element-containing grind disc) suitable for grinding silicon carbide. In some embodiments, the abrasive elements may include one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide. In this way, the polishing system may be adapted for implementing a grinding operation on a silicon carbide wafer.

In some examples, the workpiece carrier may present the entire surface of the silicon carbide semiconductor wafer at the same time. In this way, non-uniformities such as center dimple and edge roll may be reduced relative to, for instance, Blanchard grinding processes that only present a portion of the semiconductor wafer to the surface of a grinding wheel at any given instant of time.

The grind disc may include an abrasive surface. The abrasive surface may include an abrasive containing material. The abrasive containing material may be suitable for grinding silicon carbide. The abrasive containing material may include a plurality of abrasive elements (e.g., abrasive particles) in a host material or matrix. In some examples, the host material may include one or more of vitreous material, metal, resin, and/or other sintered material and/or organic material. In some embodiments, the abrasive elements may be diamond or a diamond coated material. In some embodiments, the abrasive elements may include a ceramic material. Example ceramic materials may include, for instance, boron carbide (B₄C) and cubic boron nitride (BN). In some examples, the abrasive elements may include one or more metal oxides (sintered and/or unsintered). In some embodiments, the abrasive elements may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the abrasive elements of the abrasive containing material of the grind disc may have a hardness in a range of about 7 Mohs to about 10 Mohs, such as about 10 Mohs. In some examples, the abrasive elements of the abrasive containing material of the grind disc may include a plurality of abrasive particles. In some examples, the abrasive elements of the abrasive containing material of the grind disc may have a grit size. The grit size of the abrasive elements may be in a range of about FEPA grit size F500 to about FEPA grit size F90,000, such as a range of about FEPA grit size F500 to about FEPA grit size F14000, such as about FEPA grit size F600 to about FEPA grit size F1200.

In some examples, the grind disc may have a first surface and an opposing second surface. The second surface may be facing toward the platen such that the first surface is presented to a silicon carbide semiconductor wafer for grinding. According to example aspects of the present disclosure, at least about 75% of a surface area of the first surface of the grind disc may be an abrasive surface including an abrasive containing material, such as about 85% of the surface area of first surface of the grind disc, such as about 95% of the surface area of the first surface of the grind disc.

In some examples, the grind disc may have a diameter in a range of about 150 millimeters to about 820 millimeters, such as in a range of about 150 millimeters to about 400 millimeters, such as in a range of about 150 millimeters to about 300 millimeters. In some embodiments, the grind disc has a diameter that is within 10% of a diameter of the semiconductor to be processed on the grind disc. In some examples, the grind disc may have a thickness in a range of about 2 millimeters to about 40 millimeters, such as in a range 5 millimeters to about 40 millimeters, such as in a range of about 10 millimeters to about 40 millimeters.

In some examples, one or more additives may be used in conjunction with the grind disc that provide for higher removal rates and to allow for finer grit sizes. In some examples, the one or more additives may act as lubricant that helps flushing out removed or broken-down grind product material. Example lubricants may include, for instance, any material capable of reducing friction between the abrasive material of the grind disc and the semiconductor wafer. Example lubricants may include, for instance, organic oils, fatty acids, and/or alcohols with multi-OH groups (polyols).

In some examples, the one or more additives may act as a coagulant that prevents small particles from sizing up the active surface. Example coagulants include inorganic salts, such as aluminum chloride, aluminum sulfate, sodium aluminate, ferrous sulfate, ferric sulfate, ferric chloride, and the like.

In some examples, the one or more additives may act as chemical reactant to dissolve and/or transform removed or broken-down material such as particles and oxides. In some examples, the one or more additives may act as a chemical reactant that helps break down the abrasive surface in order to expose new active surface. In some examples, the one or more additives may react with the wafer surface to form an easier to remove component.

In some examples, the additive may include an oxidizing agent. In some examples, the oxidizing agent may include, for instance, one or more of hydrogen peroxide, urea peroxide, potassium hypochlorite, sodium hypochlorite, ammonium persulfate, potassium peroxymonosulfate, potassium permanganate, potassium periodate, and/or potassium persulfate. In some examples, the oxidizing agent may include an organic peroxide, such as one or more of benzoyl peroxide or dimethyl peroxide. In some examples, the additive may include an etching agent. In some examples, the etching agent is a caustic compound, such as potassium hydroxide, calcium hydroxide, or sodium hydroxide.

In some examples, the additive may include an actuatable material that is activated by an external stimulus (e.g., an actuator). For instance, the actuatable material may include a material that is activated by one or more of an electrostatic actuator, electrochemical actuator, acoustic actuator, ultrasonic actuator, optical actuator, thermal actuator, or plasma-based actuator. For instance, in some embodiments, the additive may be inert and not react with a surface of the grind disc and/or the silicon carbide semiconductor wafer until the material is actuated by the external actuator. In some embodiments, the additive may be activated to react with the surface of the grind disc and/or the silicon carbide semiconductor wafer only when exposed (or not exposed) to the external stimulus from the actuator. In this way, the reactive properties of the additive may be controlled (e.g., pulsed) by controlling the actuator.

In some examples, the additive may include one or more additional abrasive agents. The one or more abrasive agents may include abrasive particles. The abrasive particles may be, for instance, one or more of chromium oxide, cerium oxide, aluminum oxide, or silicon oxide. Other suitable additives may be used without deviating from the scope of the present disclosure.

The additive may be provided to the grind disc in various ways. In some examples, the additive may be added to the grind disc as a liquid and/or as a powder prior to use of the grind disc during a grind operation. In some examples, the additive may be interspersed within the abrasive surface or volume of the grind disc (e.g., in a regular grind pattern or in an irregular grind pattern). In some examples, the additive may be added to the grind disc during a grind operation as part of a coolant (e.g., deionized water) used during a grinding operation. The coolant may be delivered using a coolant delivery system (e.g., fluid delivery outlet, such as a slurry delivery outlet in a polishing system). In some examples, the additive may be added to the grind disc as part of conditioning the grind disc during the grinding operation on the polishing system. For instance, the additive may be provided from a conditioning head for the grind disc on the polishing system. In some examples, the additive may be provided to the surface of the grind disc through one or more apertures in the grind disc (e.g., through the platen during a grinding operation).

In some examples, combinations of any of the above methods of providing the additive may be used without deviating from the scope of the present disclosure. For instance, a first additive may be provided as part of a grind disc. A second additive may be provided to the grind disc during a grinding operation, for instance, through a coolant delivery system, through the conditioning head, through apertures in the grind disc and/or in other ways. In some examples, the first additive may be an activation agent for the second additive or vice versa. For instance, the first additive, when mixed with the second additive during a grind process, may activate desired properties of the second additive.

In some examples, the polishing tool may be operable in a batch mode to process a plurality of semiconductor wafers at the same time. Polishing tools that operate in a batch mode may have reduced down force during a polishing or surface processing operation. However, aspects of the present disclosure may provide for working in a batch mode while still achieving reasonable removal rates and surface finish.

In some examples, the polishing system may be operable to perform both a grinding operation and a polishing operation. For instance, process parameters may be adjusted to switch from performing a grinding operation to a polishing operation. As one example, less down force may be provided by the wafer carrier against the grind disc during the polishing operation relative to the grinding operation. In addition, a slurry (with chemical and mechanical abrasive agents) may be provided in the polishing system to perform a polishing operation. During a grinding operation, a coolant may be provided to the surface of the grind disc. In some examples, the polishing system may include multiple platens. A first platen may be for a grinding operation using a grind disc according to examples of the present disclosure. A second platen may be for performing a polishing operation (e.g., using CMP polishing). In some examples, the grind disc of the polishing system may be replaced with a polishing pad to transition from a grinding operation to a polishing operation using the polishing system according to examples of the present disclosure.

Aspects of the present disclosure provide a number of technical effects and benefits. For instance, use of a grind disc that is operable to contact an entire surface of the silicon carbide semiconductor wafer at the same time may lead to reduced non-uniformities, such as reduced center dimple and reduced edge roll off. Adaptation of the grind disc in a polishing system, such as in a CMP system, may facilitate the delivery of additives to assist with the grinding operations, resulting in reasonable removal rates and surface finish, even with the use of batch processing tools.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

In the drawings and specification, there have been disclosed typical embodiments and, although specific terms are employed, they are used in a generic and descriptive sense only and not for purposes of limitation of the scope set forth in the following claims.

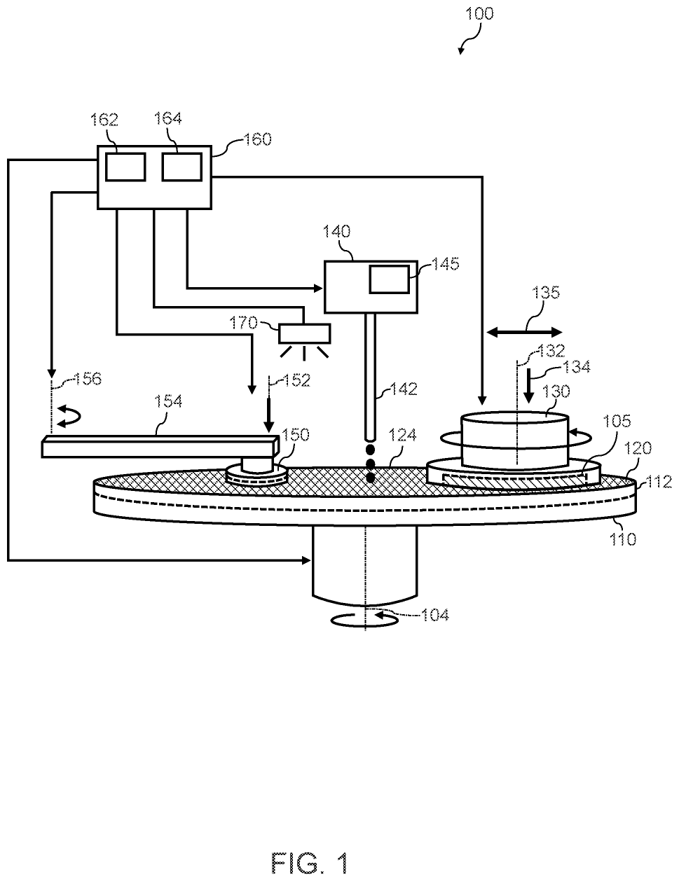

FIG. 1 depicts an example polishing system 100 for a silicon carbide semiconductor wafer 105 according to example embodiments of the present disclosure. The polishing system 100 is similar to a CMP system, however, the polishing system 100 is operable to perform a grinding operation (e.g., a coarse grinding operation or a fine grinding operation) for a silicon carbide semiconductor wafer 105. The silicon carbide semiconductor wafer 105 may include 4H silicon carbide, 6H silicon carbide or other crystal structure. The silicon carbide wafer 105 may be doped or undoped. The polishing system 100 includes a platen 110, a grind disc 120, a workpiece carrier 130, a fluid delivery system 140, a conditioning head 150, and a controller 160.

More specifically, the polishing system 100 includes the platen 110. The platen 110 may be operable to rotate about an axis 104. The platen 110 may be operable to rotate about the axis 104 in either a clockwise or counterclockwise direction. In some examples, the platen 110 may rotate, for instance, at a rotational speed in a range of about 40 rpm to about 10000 rpm, such as about 40 rpm to about 7500 rpm, such as about 40 rpm to about 2000 rpm, such as about 40 rpm to about 1000 rpm, such as about 40 rpm to about 500 rpm, such as about 40 rpm to about 120 rpm. Higher rotational speeds, such as between 200 rpm and 10000 rpm may be beneficial for grinding process(s) using a grind disc according to examples of the present disclosure.

The platen 110 may include a receptacle 112. The receptacle 112 may typically be configured to hold a polishing pad for a CMP process. However, according to examples of the present disclosure, the receptacle 112 holds the grind disc 120. The receptacle 112 may be a surface configured to support or receive the grind disc 120. In some examples, the receptacle 112 may be a planar surface that supports the grind disc 120.

The grind disc 120 may be configured to grind silicon carbide. The grind disc 120 may have a first surface and an opposing second surface. The second surface may face the platen 110 such that the first surface is exposed for grinding the silicon carbide semiconductor wafer 105. The first surface of the grind disc 120 may include a continuous surface of an abrasive containing material 124 such that at least 75% of a surface area of the first surface of the grind disc 120 is an abrasive containing material having a plurality of abrasive elements (e.g., abrasive particles), such as at least 85% of the surface area of the first surface of the grind disc 120, such as at least 95% of the surface area of the first surface the grind disc 120. In this way, substantially the entire surface of the grind disc 120 provides a abrasive surface for a grinding operation.

The abrasive containing material 124 of the grind disc 120 may be sufficient to perform a grinding operation (e.g., a coarse grinding operation) on silicon carbide. In some embodiments, the grinding operation may be a coarse grinding operation or a fine grinding operation.

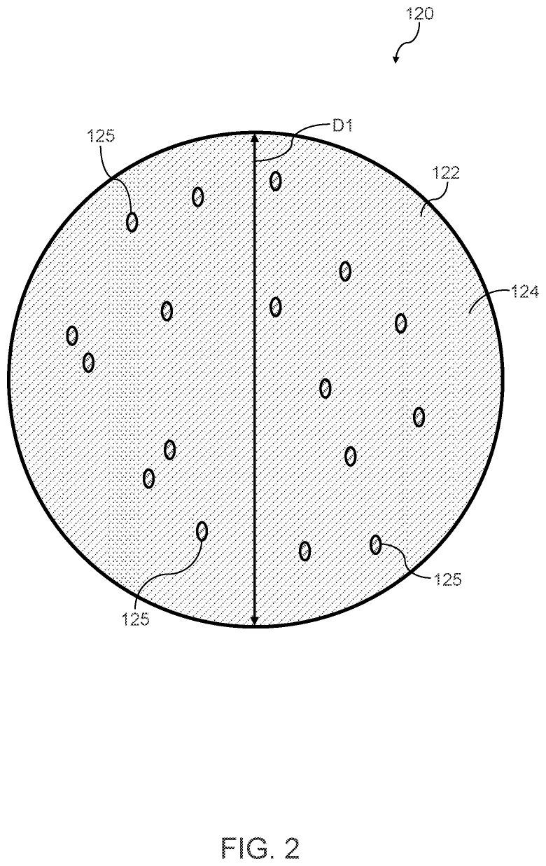

FIG. 2 depicts a plan view of an example grind disc 120 according to example embodiments of the present disclosure. The grind disc 120 includes an abrasive containing material 124 over substantially the entire surface 122 of the grind disc 120. More specifically, at least about 75% of a surface area of the surface 122 may include the abrasive containing material 124. In some embodiments, at least about 85% of the surface area of the first surface 122 may include the abrasive containing material 124. In some embodiments, at least about 95% of the surface area of the first surface 122 may include the abrasive containing material 124.

The abrasive containing material 124 may be suitable for grinding silicon carbide. The abrasive containing material 124 may include a plurality of abrasive elements (e.g., abrasive particles) in a host material or matrix. In some examples, the host material may include one or more of vitreous material, metal, resin, and/or other sintered material and/or organic material. In some embodiments, the abrasive elements may be diamond or a diamond coated material. In some embodiments, the abrasive elements may include a ceramic material. Example ceramic materials may include, for instance, boron carbide (B₄C) and cubic boron nitride (BN). In some examples, the abrasive elements may include one or more metal oxides (sintered and/or unsintered). In some embodiments, the abrasive elements may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

The grind disc 120 may have a diameter D1. The diameter D1 may be greater than a size of the silicon carbide semiconductor wafer 105. The grind disc 120 may have a diameter D1 in a range of, for instance, about 150 millimeters to about 820 millimeters, such as in a range of about 150 millimeters to about 400 millimeters, such as in a range of about 150 millimeters to about 300 millimeters. In some examples, the diameter D1 of the grind disc 120 may be smaller or nearly the same size as the diameter of the platen 110 (FIG. 1). However, the diameter D1 of the grind disc 120 may be larger than the diameter of the platen 110 without deviating from the scope of the present disclosure. In some examples, the grind disc may have a thickness in a range of about 2 millimeters to about 40 millimeters, such as in a range 5 millimeters to about 40 millimeters, such as in a range of about 10 millimeters to about 40 millimeters.

In some examples, the abrasive elements of the grind disc 120 may have a hardness in a range of about 7 Mohs to about 10 Mohs, such as about 10 Mohs. In some examples, the abrasive elements of the grind disc 120 may include a plurality of abrasive particles. In some examples, the abrasive elements of the grind disc may have a grit size. The grit size of the abrasive elements may be in a range of about FEPA grit size F500 to about FEPA grit size F90,000, such as a range of about FEPA grit size F500 to about FEPA grit size F14000, such as about FEPA grit size F600 to about FEPA grit size F1200.

In some examples, the grind disc 120 may include an additive 125. The additive 125 is represented in FIG. 2 as larger circles on the surface 122 of the grind disc 120. The additive 125 may be added as a liquid or a powder to the grind disc 120 prior to or during a grinding operation. In some examples, the additive 125 is embedded as part of the grind disc 120, such as interspersed among abrasive containing material 124 in the grind disc 120. The additive 125 may be in the form of a liquid and/or a solid (e.g., powder) on the grind disc. The additive 125 in the example grind disc 120 of FIG. 2 is in an irregular pattern.

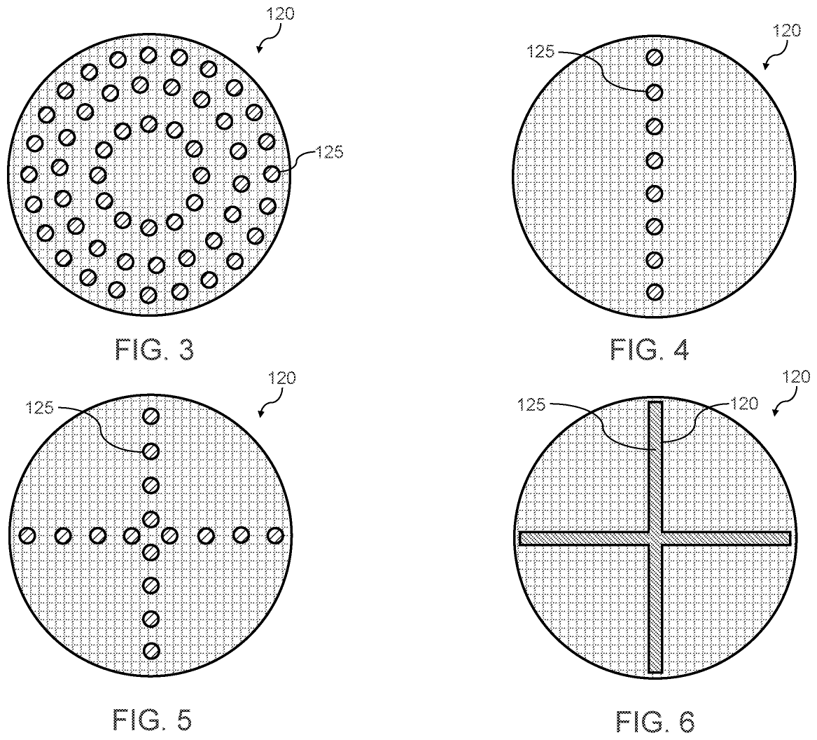

The additive 125 may be provided in different patterns (e.g., regular patterns) on the grind disc 120 without deviating from the scope of the present disclosure. For instance, FIG. 3 depicts a grind disc 120 with the additive 125 on the grind disc 120. The additive 125 is in a pattern, such as concentric circles on the grind disc 120. FIG. 4 depicts a grind disc 120 with the additive 125 on the grind disc 120. The additive 125 is in a pattern, such as a single line on the grind disc 120. FIG. 5 depicts a grind disc 120 with the additive 125 in intersecting lines on the grind disc 120.

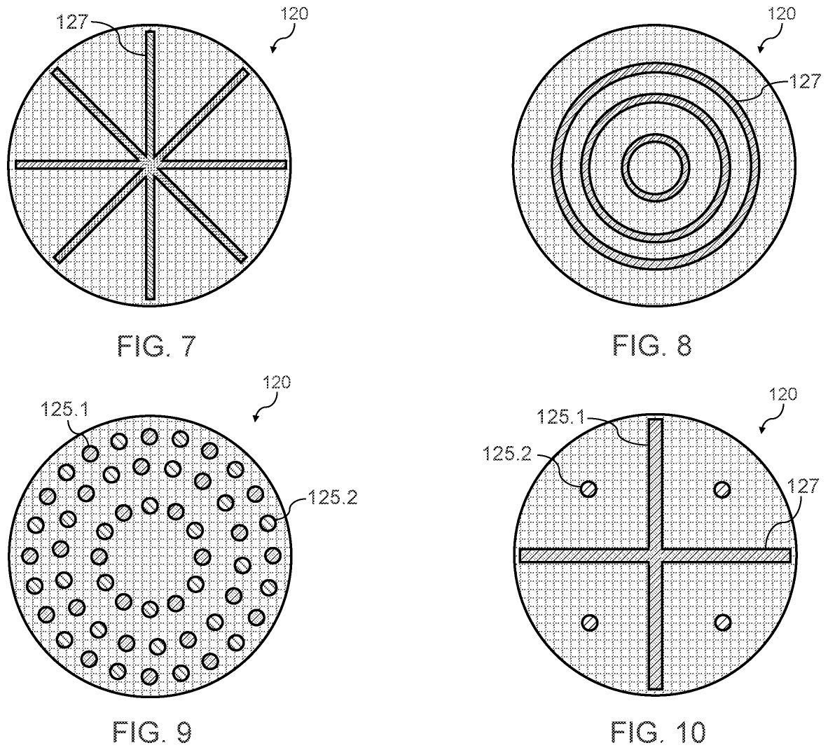

FIG. 6 depicts a grind disc 120 with grooves 127. The grooves 127 may be in intersecting lines as shown in FIG. 6. The grooves 127 may contain the additive 125 according to example embodiments of the present disclosure. The grooves 127 may be arranged in different patterns on the grind disc 120 without deviating from the scope of the present disclosure. For instance, the grooves 127 may be in a hub and spoke pattern as shown in FIG. 7. The grooves 127 may be in the form of concentric circles as shown FIG. 8.

FIG. 9 depicts a grind disc 120 with a plurality of different types of additive on the grind disc 120. For instance, the grind disc 120 may include a first additive 125.1 and a second additive 125.2. The first additive 125.1 may be a first additive type for a first purpose (e.g., lubricant). The second additive 125.2 may be a second additive type for a second purpose (e.g., etchant, coagulant, etc.). The grind disc 120 may include more additive types (e.g., a third additive type, a fourth additive type, etc.) without deviating from the scope of the present disclosure. In some examples, the first additive 125.1 may be an activation agent for the second additive 125.2 or vice versa. For instance, the first additive 125.1, when mixed with the second additive 125.2 during a grind process, may activate desired properties of the second additive 125.2.

FIG. 9 depicts the first additive 125.1 and the second additive 125.2 in a concentric circle pattern for purposes of illustration and discussion. Other patterns may be used without deviating from the scope of the present disclosure. For instance, the first additive 125.1 may be in intersecting grooves 127 on the grind disc 120 while the second additive 125.2 is on the surface of the grind disc 120 interspersed between the abrasive containing material as shown in FIG. 10.

The additive 125 may be in the form of a liquid or a solid (e.g., powder) on the grind disc. The example additive 125 on the grind disc 120 as shown in FIGS. 2-10 may provide higher removal rates and finer grit sizes. In some examples, the additive 125 may act as lubricant that helps flushing out removed or broken-down grind product material. Example lubricants may include, for instance, any material capable of reducing friction between the abrasive material of the grind disc and the semiconductor wafer. Example lubricants may include, for instance, organic oils, fatty acids, and/or alcohols with multi OH groups (polyols).

In some examples, the additive 125 may act as a coagulant that prevents small particles from sizing up the active surface. Example coagulants include inorganic salts, such as aluminum chloride, aluminum sulfate, sodium aluminate, ferrous sulfate, ferric sulfate, ferric chloride, and the like.

In some examples, the additive 125 may act as chemical reactant to dissolve and/or transform removed or broken-down material such as particles and oxides. In some examples, the additive 125 may act as a chemical reactant that helps breaking down the abrasive surface in order to expose new active surface. In some examples, the additive 125 may react with the wafer surface to form an easier to remove component.

In some examples, the additive 125 may include an oxidizing agent. In some examples, the oxidizing agent may include, for instance, one or more of hydrogen peroxide, urea peroxide, potassium hypochlorite, sodium hypochlorite, ammonium persulfate, potassium peroxymonosulfate, potassium permanganate, potassium periodate, and/or potassium persulfate. In some examples, the oxidizing agent may include an organic peroxide, such as one or more of benzoyl peroxide or dimethyl peroxide. In some examples, the additive 125 may include an etching agent. In some examples, the etching agent is a caustic compound, such as potassium hydroxide, calcium hydroxide, or sodium hydroxide.

In some examples, the additive 125 may include an actuatable material that is activated by an external stimulus (e.g., an actuator 170 described below). For instance, in some embodiments, the additive 125 may be inert and not react with a surface 122 of the grind disc 120 and/or the silicon carbide semiconductor wafer 105 until the material is actuated by the external actuator (e.g., actuator 170). In some embodiments, the additive 125 may be activated to react with the surface 122 of the grind disc 120 and/or the silicon carbide semiconductor wafer 105 only when exposed (or not exposed) to the external stimulus from the actuator (e.g., actuator 170). In this way, the active properties of the additive may be controlled (e.g., pulsed) by controlling the actuator 170.

Referring to FIG. 1, the polishing system 100 includes a workpiece carrier 130. The workpiece carrier 130 is operable to bring one or more silicon carbide semiconductor wafers 105 into contact with the grind disc 120 to implement a grinding operation. In some examples, the workpiece carrier 130 may be operable to hold a single silicon carbide semiconductor wafer 105 for single wafer processing. In some examples, the workpiece carrier 130 may be operable to hold a plurality of silicon carbide semiconductor wafers 105 for batch processing.

The workpiece carrier 130 may be operable to rotate the silicon carbide semiconductor wafer 105 about an axis 132. The axis 132 is not aligned with the axis 104 associated with the platen 110. The workpiece carrier 130 may be operable to rotate the silicon carbide semiconductor wafer about the axis 104 in either a clockwise or counterclockwise direction. In some examples, the workpiece carrier 130 may rotate, for instance, at a rotational speed in range of about 40 rpm to about 10000 rpm, such as about 40 rpm to about 7500 rpm, such as about 40 rpm to about 2000 rpm, such as about 40 rpm to about 1000 rpm, such as about 40 rpm to about 500 rpm, such as about 40 rpm to about 120 rpm. Higher rotational speeds, such as between 200 rpm and 10000 rpm may be beneficial for grinding process(s) using a grind disc according to examples of the present disclosure. The workpiece carrier 130 may rotate in the same direction as the platen 110 or in a different direction relative to the platen 110.

The workpiece carrier 130 may be able to provide a downforce 134 of the silicon carbide semiconductor wafer 105 against the grind disc 120. The downforce 134 of the workpiece carrier 130 may be controlled to adjust the grinding rate of the grinding operation of the silicon carbide semiconductor wafer 105. A higher down force 134 may result in a faster grinding rate.

The workpiece carrier 130 may also oscillate in a lateral direction 135 along the surface of the grind disc 120. This will allow exposure of the silicon carbide semiconductor wafer 105 to different portions of the grind disc 120 (e.g., at different radii of the grind disc 120) during a grinding operation.

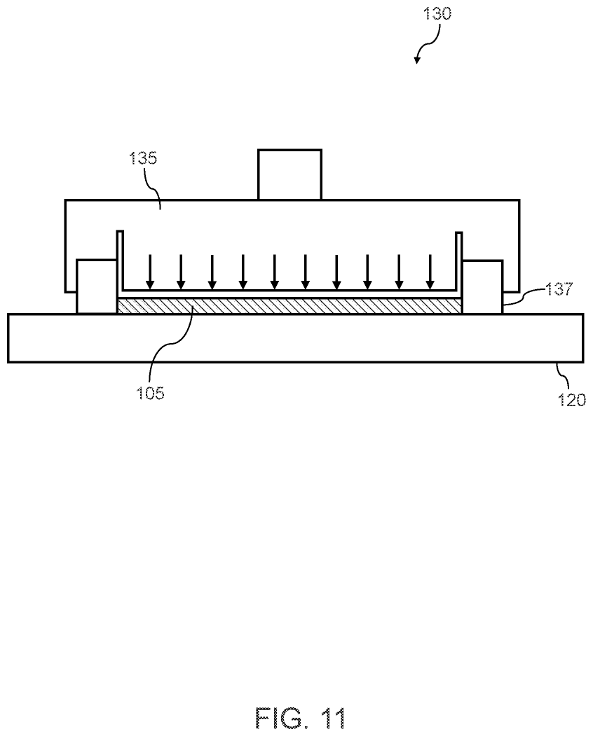

FIG. 11 depicts a cross-sectional view of an example workpiece carrier 130 according to an example embodiment of the present disclosure. The workpiece carrier 130 of FIG. 3 is operable to hold a single silicon carbide semiconductor wafer 105 for single wafer processing. The workpiece carrier 130 may include a retaining ring 137 operable to hold a silicon carbide semiconductor wafer 105. The workpiece carrier 130 may include an air cushion 135 or other actuator for pressing the silicon carbide semiconductor wafer 105 against the grind disc 120 during a grinding operation.

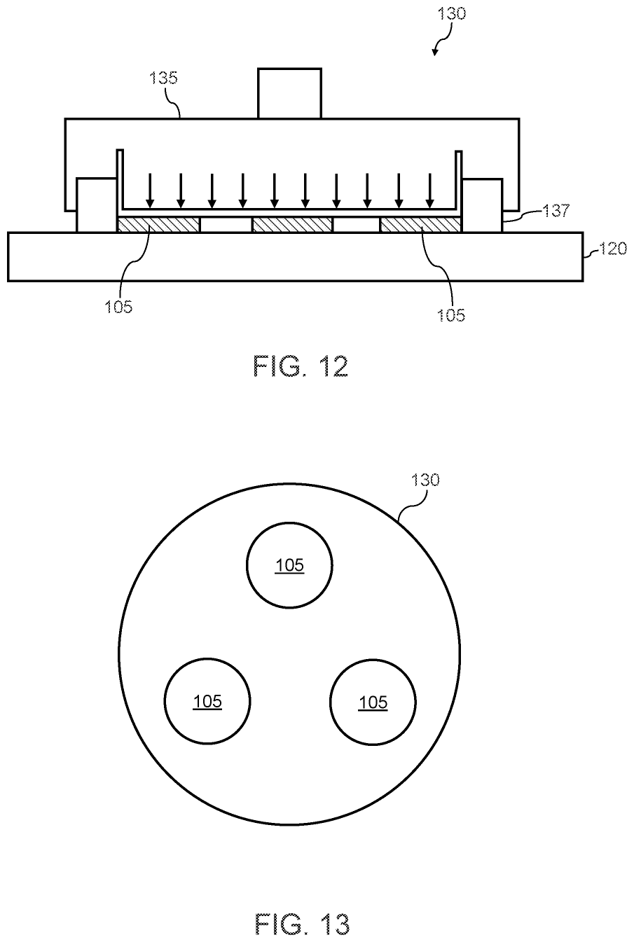

FIG. 12 depicts a cross-sectional view of another example workpiece carrier 130 according to an example embodiment of the present disclosure. The workpiece carrier 130 of FIG. 12 is operable to hold a plurality of silicon carbide semiconductor wafers 105 for batch processing. The workpiece carrier 130 may include a retaining ring 137 operable to hold the silicon carbide semiconductor wafers 105. The workpiece carrier 130 may include an air cushion 135 or other actuator for pressing the silicon carbide semiconductor wafers 105 against the grind disc 120 during a grinding operation. FIG. 12 depicts a plan view of the workpiece carrier 130 of FIG. 12. As shown in FIG. 13, the workpiece carrier 130 may hold the plurality of silicon carbide semiconductor wafers 105 in a pinwheel configuration for batch processing. Other suitable configurations of the plurality of semiconductor wafers may be used without deviating from the scope of the present disclosure.

Referring back to FIG. 1, the polishing system 100 may include a fluid delivery system 140. The fluid delivery system 140 may typically be used to deliver a slurry to a polishing pad held on the platen 110 during a CMP process. However, during a grind process, such as a coarse grind process or a fine grind process, the fluid delivery system 140 may be configured to deliver a coolant (e.g., deionized water) to the surface of the grind disc 120, for instance, through a fluid delivery outlet 142. The fluid delivery system 140 is depicted as having a single fluid delivery outlet 142 for purposes of illustration and discussion. Those of ordinary skill in the art, using the disclosures provided herein, will understand that the polishing system 100 may include multiple fluid delivery outlets arranged to deliver a fluid to the surface of the grind disc 120 without deviating from the scope of the present disclosure.

In some examples, the fluid delivery system 100 may include or be coupled to an additive delivery system 145. The additive delivery system 145 may be configured to provide one or more additives with the coolant provided to the surface of the grind disc 120 through the fluid delivery system 140.

As discussed above, one or more additives may provide for higher removal rates and finer grit sizes. In some examples, the one or more additives may act as lubricant that helps flushing out removed or broken-down grind product material. Example lubricants may include, for instance, any material capable of reducing friction between the abrasive material of the grind disc and the semiconductor wafer. Example lubricants may include, for instance, organic oils, fatty acids, and/or alcohols with multi OH groups (polyols).

In some examples, the one or more additives may act as a coagulant that prevents small particles from sizing up the active surface. Example coagulants include inorganic salts, such as aluminum chloride, aluminum sulfate, sodium aluminate, ferrous sulfate, ferric sulfate, ferric chloride, and the like.

In some examples, the one or more additives may act as chemical reactant to dissolve and/or transform removed or broken-down material such as particles and oxides. In some examples, the one or more additives may act as a chemical reactant that helps breaking down the abrasive surface in order to expose new active surface. In some examples, the one or more additives may react with the wafer surface to form an easier to remove component.

In some examples, the additive may include an oxidizing agent. In some examples, the oxidizing agent may include, for instance, one or more of hydrogen peroxide, urea peroxide, potassium hypochlorite, sodium hypochlorite, ammonium persulfate, potassium peroxymonosulfate, potassium permanganate, potassium periodate, and/or potassium persulfate. In some examples, the oxidizing agent may include an organic peroxide, such as one or more of benzoyl peroxide or dimethyl peroxide. In some examples, the additive may include an etching agent. In some examples, the etching agent is a caustic compound, such as potassium hydroxide, calcium hydroxide, or sodium hydroxide.

In some examples, the additive may include an actuatable material that is activated by an external stimulus (e.g., an actuator). For instance, the actuatable material may include a material that is activated by one or more of an electrostatic actuator, electrochemical actuator, acoustic actuator, ultrasonic actuator, optical actuator, thermal actuator, or plasma-based actuator. For instance, in some embodiments, the additive may be inert and not react with a surface of the grind disc and/or the silicon carbide semiconductor wafer until the material is actuated by the external actuator. In some embodiments, the additive may be activated to react with the surface of the grind disc and/or the silicon carbide semiconductor wafer only when exposed (or not exposed) to the external stimulus from the actuator. In this way, the active properties of the additive may be controlled (e.g., pulsed) by controlling the actuator.

In some examples, the additive may be activated when it interacts (e.g., mixes, contacts, etc.) other additives or components in the grinding system. For instance, the additive may interact with other additives already present on the semiconductor wafer and/or the grind disc to activate properties of the additive.

In some examples, the additive may include one or more additional abrasive agents. The one or more abrasive agents may include abrasive particles. The abrasive particles may be, for instance, one or more of chromium oxide, cerium oxide, aluminum oxide, or silicon oxide. Other suitable additives may be used without deviating from the scope of the present disclosure.

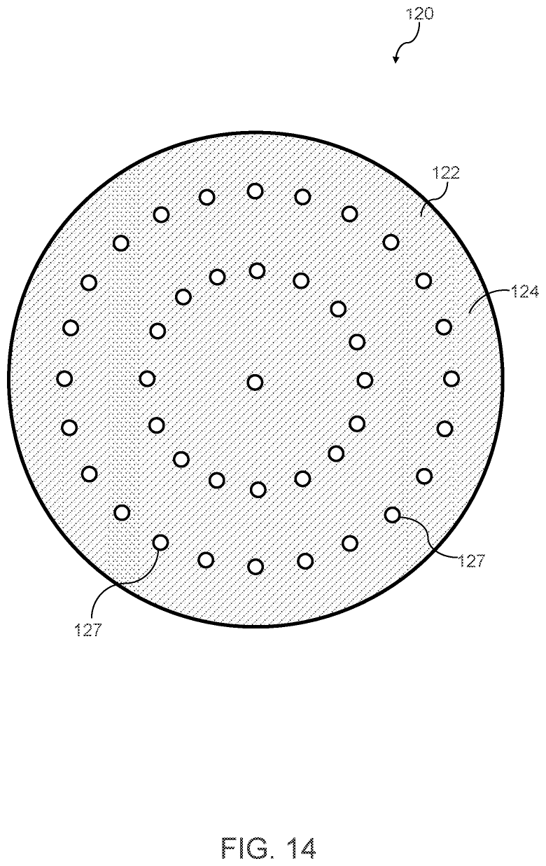

The additive may be provided to the surface of the grind disc 120 in other ways without deviating from the scope of the present disclosure. For instance, FIG. 14 depicts an example grind disc 120 having one or more apertures 127 that may be used to deliver a fluid including one or more additives to a surface 122 of the grind disc 120 having the abrasive containing material. The apertures 127 are depicted in an example pattern of concentric circles for purposes of illustration and discussion. Other suitable patterns and/or irregular spacing of the apertures 127 may be used without deviating from the scope of the present disclosure. The apertures 127 may be fluidly coupled to a fluid delivery system that deliver fluid, for instance, through the platen 110 through the apertures 127 to the surface 124 of the grind disc 120. In some examples, different amounts of fluid may be provided through different apertures 127. For instance, more fluid may be provided through apertures 127 close to the periphery of the grind disc 120 relative to apertures 127 close to a center of the grind disc 120, or vice versa.

In addition to apertures 127, or in the alternative, the grind disc 120 may include one or more perforations, deformation, holes, gaps, etc. to hold, retain, transport, or deliver an additive. In some examples, portions of the grind disc 120 may be porous to retain fluid additive for a grinding process.

Referring to FIG. 1, the polishing system 100 may include a conditioning head 150. The conditioning head 150 may rotate about an axis 152, such that the conditioning head 150 rotates along the surface of the grind disc 120 (e.g., in either a clockwise or counterclockwise direction). In some examples, the conditioning head 150 may be on a swing arm 154 that may swing about an axis 156 to move the conditioning head 150 to different locations on the grind disc 120. The conditioning head 150 may include an abrasive-containing material that is used to condition or dress the grind disc 120 as the grind disc is subject to glazing during a grinding process. In some examples, the conditioning head 150 may condition the grind disc 120 with an additive, such as any of the additives described herein. The additive may be provided to the grind disc using a combination of any of the above-described methods and other methods without deviating from the scope of the present disclosure.

For instance, in some examples a first additive may be included as part of a grind disc 120 (e.g., a liquid or a powder on the grind disc). A second additive may be provided to the grind disc 120 during a grinding operation, for instance, through a fluid delivery system 140, through the conditioning head 150, through apertures 127 in the grind disc 120 or in other ways. In some examples, the first additive may be an activation agent for the second additive or vice versa. For instance, the first additive, when mixed with the second additive during a grind process, may activate desired properties of the second additive.

In some examples, as described above, the polishing system 100 may include an actuator 170. The actuator 170 may be configured to provide a stimulus to an additive on the surface of the grind disc 120 to activate properties (e.g., reactive properties) of the additive. The actuator 170 may be any suitable device operable to provide a stimulus to the additive.

In some examples, the actuator 170 includes one or more of an electrostatic actuator, electrochemical actuator, acoustic actuator, ultrasonic actuator, optical actuator, ultraviolet actuator, thermal actuator, or plasma-based actuator. An electrochemical actuator may be operable to provide an electrochemical stimulus to the additive. An acoustic actuator may be operable to provide an acoustic stimulus to the additive. An ultrasonic actuator may be configured to provide an ultrasonic stimulus to the additive. An optical actuator may be configured to provide an optical stimulus to the additive. A thermal actuator may be operable to provide a heat stimulus to the additive (e.g., heat source, laser, lamp, etc.). An ultraviolet actuator may be operable to provide UV light stimulus to the additive. A plasma-based actuator may be operable to generate a plasma to act as a stimulus to the additive.

In some examples, for instance, an ultraviolet actuator may provide UV light stimulus to provide photochemical activation and/or photocatalytic effects in an actuatable additive, such as hydrogen peroxide and/or organic peroxide to generate, for instance, hydroxyl radicals. In some examples, activation of additives (e.g. photo activation of additives) may include using catalytic effects provided by providing elements or components in contact with the additive, such as CeO₂ elements, TiO₂ elements, or other metals and metal oxides in general.

In some embodiments, the additive may be inert and not react with a surface 122 of the grind disc 120 and/or the silicon carbide semiconductor wafer 105 until the material is actuated by stimulus from the actuator 170. In some embodiments, the additive may be activated to react with the surface 122 of the grind disc 120 and/or the silicon carbide semiconductor wafer 105 only when exposed (or not exposed) to the external stimulus from the actuator 170. In this way, the active properties of the additive may be controlled (e.g., pulsed) by controlling the actuator 170. For instance, by pulsing the actuator 170, the active properties of the additive are also pulsed.

In some examples, the additive may be activated when it interacts (e.g., mixes, contacts, etc.) other additives or components in the grinding system 100. For instance, the additive may interact with other additives already present on the semiconductor wafer 105 and/or the grind disc 120 to activate properties of the additive.

The system 100 includes one or more control devices, such as a controller 160. The controller 160 may include one or more processors 162 and one or more memory devices 164. The one or more memory devices 164 may store computer-readable instructions that when executed by the one or more processors 162 cause the one or more processors 162 to perform one or more control functions, such as any of the functions described herein. The controller 160 may be in communication with various other aspects of the system 100 through one or more wired and/or wireless control links. The controller 160 may send control signals to the various components of the system 100 (e.g., the platen 110, the workpiece carrier 130, the fluid delivery system 140, the conditioning head 150) to implement a grinding operation on the silicon carbide semiconductor wafer 105.

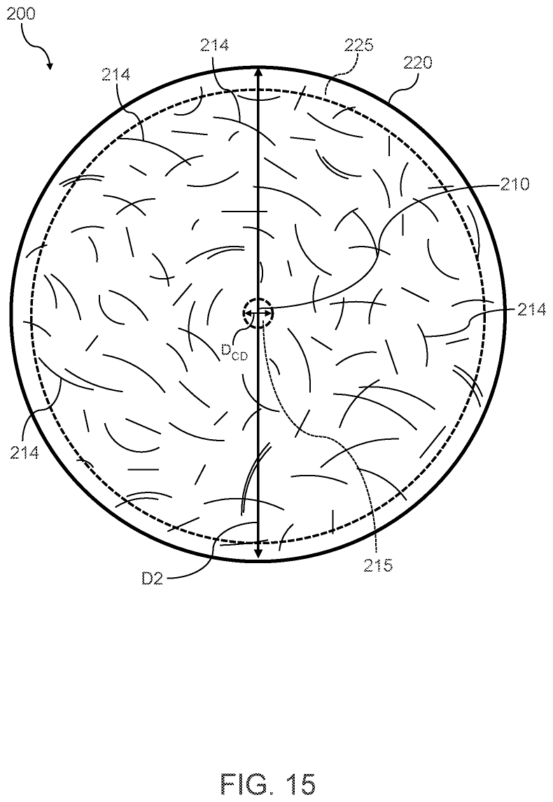

FIG. 15 depicts a plan view of an example silicon carbide semiconductor wafer 200 having a silicon carbide surface. In some examples, the silicon carbide semiconductor wafer 200 may be, for instance, 4H silicon carbide or 6H silicon carbide.

In some examples, the silicon carbide semiconductor wafer 200 has a diameter D2 in a range of about 150 millimeters to about 300 millimeters, such as in a range of about 150 millimeters to about 200 millimeters, such as about 150 millimeters, such as about 200 millimeters. The silicon carbide semiconductor wafer 200 may have thickness of less than about 500 microns, such as less than about 300 microns, such as less than about 200 microns, such as in a range of about 100 microns to about 200 microns, such as in a range of about 120 microns to 180 microns.

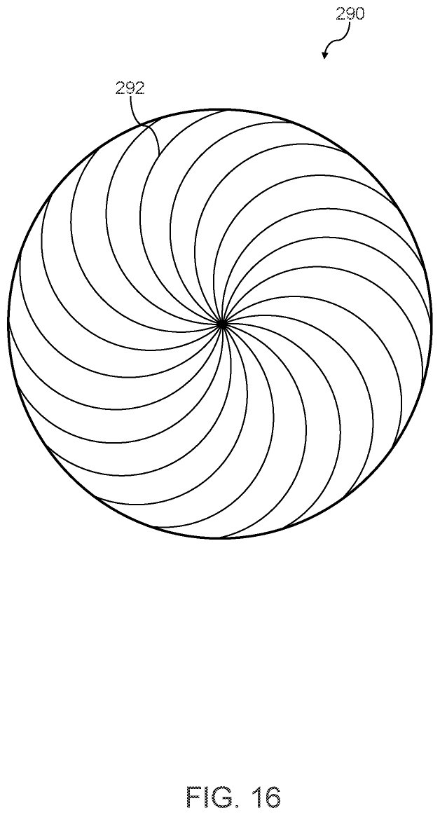

The silicon carbide semiconductor wafer 200 may have a grind disc defined grind pattern 214 on the silicon carbide surface. The grind disc defined grind pattern 214 is associated with a grinding operation performed by a grind disc, such as by the grind disc 120 of FIGS. 1-3 and 7. As illustrated, the grind disc defined grind pattern 214 is an irregular grind pattern 214 with no regular repeating structures. An irregular pattern is a pattern with no repeating structures. The grind disc defined grind pattern 214 may be distinguished from, for instance, a Blanchard grind pattern. A Blanchard grind pattern has more of one or more repeating spiral structures 292 as shown on the semiconductor wafer 290 of FIG. 16. In some examples, after polishing, the remnants of the Blanchard grind pattern may be apparent by the presence of latent grind grooves in a pattern (e.g., hub and spoke pattern) on the semiconductor wafer 290. FIG. 16 depicts a “perfect” Blanchard grind pattern for purposes of illustration and discussion. Those of ordinary skill in the art, using the disclosures provided herein, will understand that a Blanchard pattern is characterized by one or more of the spiral structures 292 shown in FIG. 16 in regular or at irregular intervals on different portions of the surface of the semiconductor wafer 290. In this regard, the grind disc defined grind pattern 214, due to not having one or more spiral structures, may be considered a non-Blanchard grind pattern.

The silicon carbide semiconductor wafer 200 has low center dimple and low edge roll. Center dimple may be measured in a region 215 inside a defined diameter D_{CD} (e.g., the center dimple diameter) from the center 210 of the silicon carbide semiconductor wafer 200. The center dimple is indicative of a difference between a representative highest surface point of the silicon carbide semiconductor wafer 200 in the region 215 in the center dimple diameter D_{CD} and a representative lowest surface point of the silicon carbide semiconductor wafer 200 in the region 215 in the center dimple diameter D_{CD} of the silicon carbide semiconductor wafer 200.

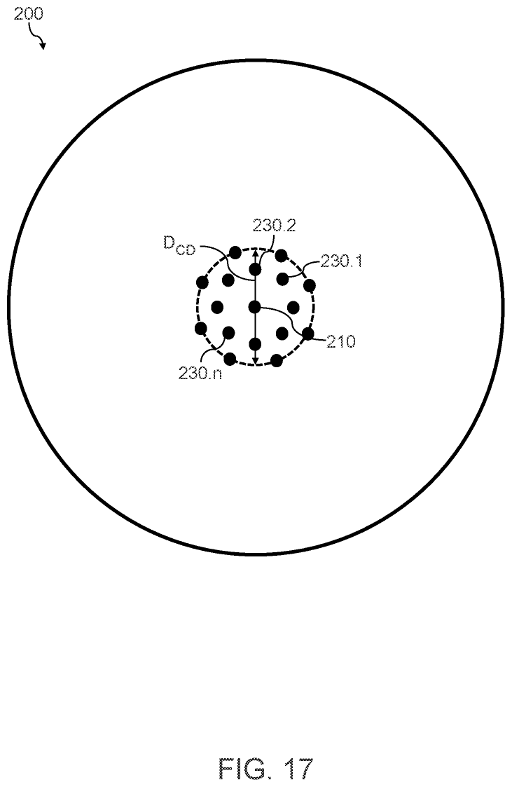

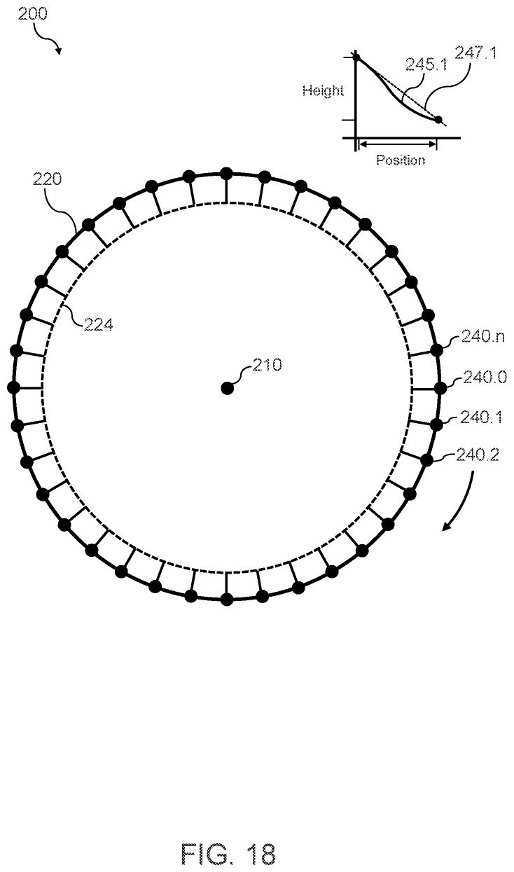

FIG. 17 depicts example determination of center dimple according to example embodiments of the present disclosure. First a topographic surface profile may be obtained for the semiconductor wafer 200 within the center dimple diameter D_{CD}. The flatness profile may be a topography and/or may include heights of the semiconductor wafer 200 at points within the center dimple diameter D_{CD}. In some examples, the center dimple diameter is 10 millimeters. The topographic surface profile may be obtained, in some embodiments, by processing data indicative of the wafer surface topography heights. Processing may include subtracting one or more Zemike shapes (e.g., 156 Zernike shapes) to obtain local shape topography in the center dimple diameter D_{CD}. A number of points 230.1, 230.2, . . . 230.n may be sampled in the center dimple diameter D_{CD}. The center dimple C_{DD} for the semiconductor wafer 200 may be determined by Pmax−Pmin, where Pmax is the maximum height of the sampled points 230.1, 230.2, . . . 230.n and Pmin is the minimum height of the sampled points 230.1, 230.2, . . . 230.n. The number of samples can be in a range of 10 samples to 1000 samples. The samples may be evenly distributed within the center dimple diameter D_{CD} or irregularly distributed.

Referring to FIG. 15, in some examples, the silicon carbide semiconductor wafer 200 may have a center dimple within a center dimple diameter D_{CD} of 10 millimeters that is in the range of or less than the areal roughness S_z of the silicon carbide semiconductor wafer outside the center dimple diameter D_{CD}. The areal roughness S_z of the semiconductor wafer is the sum of the largest peak height value of the silicon carbide semiconductor wafer 200 (relative to an average thickness surface for the semiconductor wafer) and the largest pit depth value of the semiconductor wafer (relative to the average thickness surface for the semiconductor wafer). In some embodiments, the center dimple within a center dimple diameter D_{CD} of 10 millimeters is less than about 1 micron, such as less than about 0.5 microns, such as less than about 0.1 microns, such as less than about 0.05 microns.

Referring to FIG. 15, the silicon carbide semiconductor wafer 200 has low edge roll. Edge roll may be measured by taking a topography of the semiconductor wafer 200 within an edge roll region 225 defined from the periphery 220 of the semiconductor wafer 200.

FIG. 18 depicts example determination of edge roll for a silicon carbide semiconductor wafer 200 according to examples of the present disclosure. First, a plurality of edge profiles are obtained that provide flatness profiles for the silicon carbide semiconductor wafer 200 from a point at the boundary 224 of the edge roll region (e.g., 10 mm of the periphery of the semiconductor wafer) to the periphery 220 of the semiconductor wafer 200. The topographic surface profile for each edge profile provides the heights of semiconductor wafer in a line from the periphery 220 of the semiconductor wafer toward the center 210 of the semiconductor wafer 220 but stops at boundary 224 of the edge roll region. An edge profile 240.0, 240.1, 240.2, . . . 240.n may be obtained for each sampled cross-section about the azimuth of the semiconductor wafer from 0° to 360°. A graphical representation of the edge profile 245.1 for sampled edge profile 240.1 is illustrated in FIG. 18. The number of sampled edge profiles may be in a range of about 360 edge profiles to about 6400 edge profiles, such as about 3600 edge profiles (e.g., an edge profile for every 1/10 degree about the azimuth of the semiconductor wafer 200). A linear fit is determined for each sampled edge profile. An example linear fit 247.1 is provided for edge profile 245.1 in FIG. 18. The linear fit is subtracted from each sampled edge profile to determine a subtracted sampled edge profile. The difference between the minimum value and maximum value of the subtracted sampled edge profile defines the edge roll for the sampled edge profile. The maximum sampled edge roll for all sampled edge profiles about the azimuth of the silicon carbide semiconductor wafer 200 is the edge roll for the silicon carbide semiconductor wafer 200.

Referring to FIG. 15, in some embodiments, the semiconductor wafer 200 has an edge roll over 10 millimeters from a peripheral edge 220 of the semiconductor wafer 200 of less than about 0.7 microns, such as less than about 0.3 microns. In some embodiments, the grinding systems and methods according to example aspects of the present disclosure may produce a plurality of semiconductor wafers. In some examples, about 90% of the semiconductor wafers in a group of 100 semiconductor wafers that have been subjected to a grinding operation using a grind disc according to examples of the present disclosure have an edge roll of less than 1 micron, such as less than 0.7 microns, such as less than 0.3 microns.

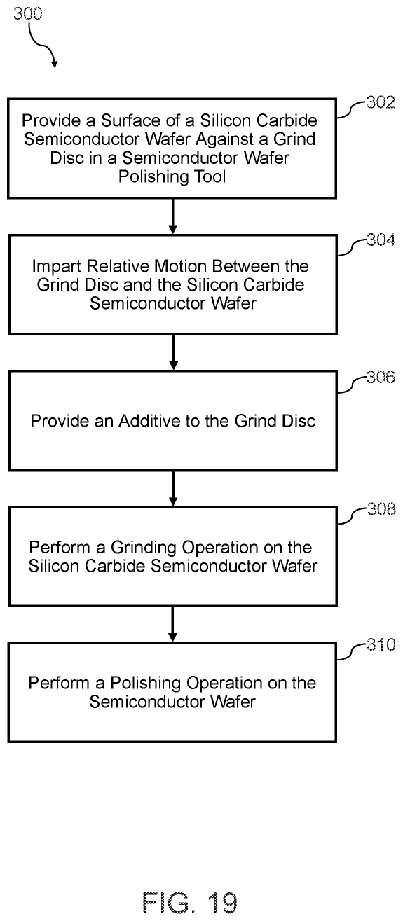

FIG. 19 depicts a flow chart of an example method 300 according to example embodiments of the present disclosure. The method 300 may be implemented, for instance, using the polishing system 100 of FIG. 1. The method 300 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 302, the method includes providing a surface of a silicon carbide semiconductor wafer against a grind disc in a semiconductor wafer polishing tool. For instance, the wafer carrier 130 of FIG. 1 may being a silicon carbide semiconductor wafer 105 into contact with the grind disc 120.

At 304, the method includes imparting relative motion between the grind disc and the silicon carbide semiconductor wafer. For instance, the wafer carrier 130 may rotate the semiconductor wafer 105 against a rotating platen 110 as depicted in FIG. 1.

At 306, the method may include providing an additive to the grind disc. The additive may be a lubricant, coagulant, or chemical reactant. In some examples, the additive may be an actuatable additive. The additive can be any of the additives described in the present disclosure.

As described above, the additive may be provided to the grind disc in various ways. For instance, in some examples, the additive may be added to the grind disc 120 of FIG. 1 as a liquid and/or as a power prior to use of the grind disc during a grind operation. In some examples, the additive may be interspersed within the abrasive containing material 124 of the grind disc 120. In some examples, the additive may be added to the grind disc 120 during a grind operation as part of a coolant (e.g., deionized water) used during a grinding operation. The coolant may be delivered using a fluid delivery system 140 (e.g., fluid delivery outlet, such as a slurry delivery outlet in a polishing system). In some examples, the additive may be added to the grind disc 120 as part of conditioning of the grind disc 120 during the grinding operation on the polishing system. For instance, the additive may be provided from a conditioning head 150 for the grind disc 120 on the polishing system 100. The additive may be provided to the grind disc 120 using a combination of any of the above-described methods and other methods without deviating from the scope of the present disclosure.

At 308, the method includes implementing a grinding operation on the silicon carbide semiconductor wafer. The grinding operation may be a coarse grinding operation. Coarse grinding operations may be used to reduce a thickness of a silicon carbide semiconductor wafer by about 20 microns to about 200 microns, such by about 20 microns to about 100 microns, such as by about 20 microns to about 80 microns, such as by about 40 microns to about 60 microns, or the like. The grinding operation may be a fine grinding operation. Fine grinding operations may be used to reduce a thickness of a silicon carbide semiconductor wafer by about 0.5 microns to about 20 microns, such as by about 3 microns to about 15 microns, such as by about 5 microns to about 10 microns, or the like.

In some examples at 310, the method can further include implementing a polishing operation using the polishing system, such as the polishing system 100 of FIG. 1. The polishing operation may be performed after the grinding operation. For instance, process parameters may be adjusted (e.g., by the controller 160) to switch from performing a grinding operation to a polishing operation using the polishing system 100. As one example, less down force 134 may be provided by the wafer carrier 130 against the grind disc 120 during the polishing operation relative to the grinding operation. In addition, a slurry (with chemical and mechanical abrasive agents) may be provided in the polishing system 100 to perform a polishing operation. The slurry may be provided through fluid delivery system 140 or a separate slurry delivery system. During a grinding operation, a coolant may be provided to the surface of the grind disc 120. In some examples, the polishing system 100 may include multiple platens. A first platen may be for a grinding operation according to examples of the present disclosure. A second platen may be for performing a polishing operation (e.g., using CMP polishing). In some examples, the grind disc 120 of the polishing system may be replaced with a polishing pad to transition from a grinding operation to a polishing operation.

One example aspect of the present disclosure is directed to a semiconductor workpiece polishing system. The semiconductor workpiece polishing system includes a platen configured to rotate about an axis. The semiconductor workpiece polishing system further includes a grind disc on the platen, the grind disc having an abrasive surface configured to grind silicon carbide. The semiconductor workpiece polishing system further includes a workpiece carrier operable to bring a silicon carbide semiconductor workpiece into contact with the grind disc to implement a grinding operation on the silicon carbide semiconductor workpiece. The grinding operation reduces a thickness of the silicon carbide semiconductor workpiece by at least about 0.5 microns.

In some examples, the grind disc is on a receptacle on the platen, the receptacle configured to hold a polishing pad for the semiconductor workpiece polishing system.

In some examples, the workpiece carrier is operable to bring the silicon carbide semiconductor workpiece into contact with the grind disc such that an entire surface of the silicon carbide semiconductor workpiece is in contact with the grind disc at the same time.

In some examples, the abrasive surface is at least about 75% of a surface area of a surface of the grind disc.

In some examples, the abrasive surface is at least about 95% of a surface area of a surface of the grind disc.

In some examples, the grind disc has a diameter in a range of about 150 millimeters to about 820 millimeters.

In some examples, the grind disc has a thickness in a range of about 2 millimeters to about 40 millimeters.

In some examples, the grind disc comprises an abrasive containing material.

In some examples, the abrasive containing material comprises one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the abrasive containing material comprises a ceramic material or an unsintered metal oxide material.

In some examples, the grind disc comprises an additive.

In some examples, the additive is one or more of a lubricant, coagulant, or chemical reactant.

In some examples, the additive comprises an oxidizing agent or a caustic compound.

In some examples, the additive is an actuatable additive.

In some examples, the system comprises an actuator operable to activate an actuatable additive.

In some examples, the system comprises a coolant delivery system configured to deliver a coolant to a surface of the semiconductor workpiece or the grind disc.

In some examples, the coolant delivery system comprises an additive delivery system configured to provide the additive to the coolant.

In some examples, the wafer polishing system comprises a conditioning head, wherein the conditioning head is configured to provide the additive to the grind disc.

In some examples, the conditioning head is on a swing arm.

In some examples, the conditioning head is configured to rotate about an axis.

In some examples, the workpiece carrier is operable to bring a plurality of silicon carbide semiconductor workpieces into contact with the grind disc for batch processing.

Another example aspect of the present disclosure is directed to a method for grinding a silicon carbide semiconductor workpiece using a semiconductor workpiece polishing system. The method includes providing an entire surface of the silicon carbide semiconductor workpiece against a grind disc. The grind disc includes an abrasive containing material configured to grind silicon carbide. The grind disc is on a platen of the semiconductor workpiece polishing tool. The abrasive containing material is on at least about 75% of a surface area of a surface of the grind disc. The method further includes imparting relative motion between the grind disc and the silicon carbide semiconductor workpiece. The method further includes performing a grinding operation on the entire surface of the silicon carbide semiconductor workpiece. The grinding operation reduces a thickness of the silicon carbide semiconductor workpiece by at least about 0.5 microns.

In some examples, the method further includes providing an additive to the grind disc.

In some examples, the additive is one or more of a lubricant, coagulant, or chemical reactant.

In some examples, the additive comprises an oxidizing agent or a caustic compound.

In some examples, the method further includes providing a coolant to the surface of the grind disc.

In some examples, providing a coolant comprises providing an additive to the coolant.

In some examples, the additive is an actuatable additive.

In some examples, the method further includes controlling an actuator to activate the actuatable additive.

In some examples, the abrasive containing material comprises one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the grind disc comprises an additive embedded as part of the grind disc.

In some examples, the additive is one or more of a lubricant, coagulant, or chemical reactant.

In some examples, the additive comprises an oxidizing agent or a caustic compound.

In some examples, the method further includes performing a polishing operation on the silicon carbide semiconductor workpiece with the semiconductor workpiece polishing system.

Another example aspect of the present disclosure is directed to a semiconductor wafer comprising silicon carbide, the semiconductor wafer having an irregular grind pattern. The semiconductor wafer has an edge roll over 10 millimeters from a peripheral edge of the semiconductor wafer of less than about 0.7 microns.

In some examples, the irregular grind pattern is a grind disc defined grind pattern.

In some examples, the irregular grind pattern is a non-Blanchard grind pattern.

In some examples, the semiconductor wafer has an edge roll over 10 mm from a peripheral edge of the semiconductor wafer of less than about 0.3 μm.

In some examples, the semiconductor wafer has a center dimple within a center dimple diameter of 10 millimeters from a center of the semiconductor wafer that is less than or in the range of an areal roughness S_z of the semiconductor wafer outside of the center dimple radius.

In some examples, the semiconductor wafer has a center dimple within a center dimple diameter of 10 millimeters from a center of the semiconductor wafer that is less than 1 micron.

In some examples, a diameter of the semiconductor wafer is about 150 millimeters.

In some examples, a diameter of the semiconductor wafer is about 200 millimeters.

Another example aspect of the present disclosure is directed to a semiconductor wafer, comprising a silicon carbide surface. The semiconductor wafer has an irregular grind pattern on the silicon carbide surface, wherein the semiconductor wafer has a center dimple within a center dimple diameter of 10 millimeters from a center of the semiconductor wafer that is less than 1 micron.

In some examples, a diameter of the semiconductor wafer is about 150 millimeters.

In some examples, a diameter of the semiconductor wafer is about 200 millimeters.

Another example aspect of the present disclosure is directed to a semiconductor wafer comprising silicon carbide. The semiconductor wafer has a non-Blanchard grind pattern, wherein has an edge roll over 10 mm from a peripheral edge of the semiconductor wafer of less than about 0.7 microns.

In some examples, a diameter of the semiconductor wafer is about 150 mm.

In some examples, a diameter of the semiconductor wafer is about 200 mm.

Another example aspect of the present disclosure is directed to a grind disc for grinding silicon carbide semiconductor wafers. The grind disc has a diameter of about 150 millimeters or greater. The grind disc has an abrasive surface with an abrasive containing material configured to grind silicon carbide. The abrasive surface is at least about 75% of a surface area of a surface of the grind disc.

In some examples, the grind disc has a thickness in a range of about 10 millimeters to about 40 millimeters.

In some examples, the abrasive containing material comprises a plurality of abrasive elements.

In some examples, the abrasive containing material comprises one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the abrasive elements comprise a ceramic or an unsintered metal oxide and in general a metal, metalloid, or crystallogen nitride, oxide, or carbide

In some examples, the grind disc has grit size in a range of about FEPA grit size F500 to about FEPA grit size F90,000.

In some examples, the grind disc comprises an additive.

In some examples, the additive is one or more of a lubricant, coagulant, or chemical reactant.

In some examples, the additive comprises an oxidizing agent or a caustic compound.

In some examples, the grind disc comprises a plurality of apertures.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor workpiece polishing system, the system comprising:
a platen configured to rotate about an axis;
a grind disc on the platen, the grind disc having an abrasive surface containing abrasive material including a plurality of abrasive elements configured to grind silicon carbide;
a workpiece carrier operable to bring a silicon carbide semiconductor workpiece into contact with the grind disc to implement a grinding operation on the silicon carbide semiconductor workpiece, the grinding operation reducing a thickness of the silicon carbide semiconductor workpiece by at least about 1 micron without an abrasive slurry;
wherein the plurality of abrasive elements includes one or more of (i) diamond; (ii) ceramic; (iii) metal nitride; (iv) metal oxide, (v) metal carbide (vi) metalloid nitride; (vii) metalloid oxide; (viii) metalloid carbide; (ix) carbon group nitride; (x) carbon group oxide; or (xi) carbon group carbide.

2. The semiconductor workpiece polishing system of claim 1, wherein the grind disc is on a receptacle on the platen, the receptacle configured to hold a polishing pad for the semiconductor workpiece polishing system.

3. The semiconductor workpiece polishing system of claim 1, wherein the workpiece carrier is operable to bring the silicon carbide semiconductor workpiece into contact with the grind disc such that an entire surface of the silicon carbide semiconductor workpiece is in contact with the grind disc at the same time.

4. The semiconductor workpiece polishing system of claim 1, wherein the grind disc has a thickness in a range of about 2 millimeters to about 40 millimeters.

5. The semiconductor workpiece polishing system of claim 1, wherein the grind disc comprises an abrasive containing material.

6. The semiconductor workpiece polishing system of claim 1, wherein the grind disc comprises an additive.

7. The semiconductor workpiece polishing system of claim 6, wherein the additive is one or more of a lubricant, coagulant, chemical reactant, oxidizing agent, or caustic compound.

8. The semiconductor workpiece polishing system of claim 6, wherein the additive is an actuatable additive.

9. The semiconductor workpiece polishing system of claim 8, wherein the system comprises an actuator operable to activate the actuatable additive.

10. The system of claim 1, wherein the system comprises a coolant delivery system configured to deliver a coolant to a surface of the semiconductor workpiece or the grind disc.

11. The semiconductor workpiece polishing system of claim 10, wherein the coolant delivery system comprises an additive delivery system configured to provide an additive to the coolant.

12.-20. (canceled)

21. The semiconductor workpiece polishing system of claim 1, wherein the abrasive surface is at least about 75% of a surface area of a first surface of the grind disc, the first surface exposed for grinding the silicon carbide semiconductor workpiece.

22. The semiconductor workpiece polishing system of claim 1, wherein the abrasive surface is at least about 95% of a surface area of a first surface of the grind disc, the first surface exposed for grinding the silicon carbide semiconductor workpiece.

23. The semiconductor workpiece polishing system of claim 1, wherein the grind disc has a diameter in a range of about 150 millimeters to about 820 millimeters.

24. (canceled)

25. The semiconductor workpiece polishing system of claim 5, wherein the abrasive containing material comprises a ceramic material or an unsintered metal oxide material.

26. The semiconductor workpiece polishing system of claim 6, wherein the semiconductor workpiece polishing system further comprises a conditioning head, wherein the conditioning head is configured to provide the additive to the grind disc.

27. The semiconductor workpiece polishing system of claim 26, wherein the conditioning head is on a swing arm.

28. The semiconductor workpiece polishing system of claim 26, wherein the conditioning head is configured to rotate about an axis.

29. The semiconductor workpiece polishing system of claim 1, wherein the workpiece carrier is operable to bring a plurality of silicon carbide semiconductor workpieces into contact with the grind disc for batch processing.

30. The semiconductor workpiece polishing system of claim 1, wherein the grinding operation reduces the thickness of the silicon carbide semiconductor workpiece by about 3 microns or greater.

31. The semiconductor workpiece polishing system of claim 1, wherein the grinding operation reduces the thickness of the silicon carbide semiconductor workpiece by about 5 microns or greater.

32. The semiconductor workpiece polishing system of claim 1, wherein the grinding operation reduces the thickness of the silicon carbide semiconductor workpiece by about 20 microns or greater.

33. The semiconductor workpiece polishing system of claim 1, wherein the platen is configured to rotate about the axis at a rotational speed of at least about 120 rpm.
